(19) United States
(12) Patent Application Publication
(10) Pub. No.: US 2012/0107992 A1
(43) Pub. Date: May 3, 2012

(54) METHOD OF PRODUCING LAYERED WAFER STRUCTURE HAVING ANTI-STICTION BUMPS

(75) Inventors: Lisa H. Karlin, Chandler, AZ (US); Hemant D. Desai, Gilbert, AZ (US)

(73) Assignee: FREESCALE SEMICONDUCTOR, INC., Austin, TX (US)

(21) Appl. No.: 12/914,908

(22) Filed: Oct. 28, 2010

(51) Int. Cl. H01L 21/302

(52) U.S. Cl. 438/50; 257/E21.214

(57) ABSTRACT

A method (50) for producing a layered wafer structure (24) having anti-stiction bumps (22) entails producing the anti-stiction bumps (22) in a surface (32) of a substrate (26) or, alternatively, in a surface (48) of a substrate (28). The method (50) further entails coupling the substrates (26, 28) with an insulator layer (30) interposed between the substrates (26, 28). A MEMS structure (20) having a movable element (34) is formed in the substrate (28) and openings (78) defining the movable element (34) extend through the substrate (28). A portion of the insulator layer (30) is removed via the openings (78) to release the movable element (34). The anti-stiction bumps (22) limit stiction between the movable element (34) and the underlying substrate (26).

### TECHNICAL FIELD OF THE INVENTION

The present invention relates generally to microelectromechanical systems (MEMS) devices. More specifically, the present invention relates to a method for producing anti-stiction bumps under MEMS devices in a layered wafer structure.

### BACKGROUND OF THE INVENTION

Microelectromechanical systems (MEMS) devices find applications in a variety of fields, such as sensing, navigation, display systems, communications, optics, micro-fluidics, measurements of material properties, and so forth. MEMS devices suffer from a phenomenon referred to as “stiction”. Stiction occurs when the movable element, also referred to as a microstructure, of the MEMS device is brought to an “intimate contact” with a surrounding surface. For example, stiction may occur after wet etching of an underlying sacrificial layer, when a liquid meniscus formed on hydrophilic surfaces of the movable element pull the movable element toward an associated substrate. Stiction can also occur during operation when the movable element of a MEMS device comes into contact, intentionally or accidentally, with the surrounding surface. In-use stiction may be caused by capillary forces, electrostatic attraction, and/or direct chemical bonding. Once in contact, Van der Waals force or hydrogen bonding on the surface exceeds the restoring spring force of the MEMS device, undesirably resulting in permanent stiction. In addition, such a stiction bonding force increases as the contact area increases.

Bumps, also commonly referred to as dimples, under MEMS devices are known in the art. However, methods of creating these bumps vary. For example, a method used to alleviate stiction uses a passivation layer to form bumps. In another method, bumps have been made by depositing, patterning, and etching of a bump material in order to form bump contact areas. In yet another method, bumps are made on a bottom surface of a MEMS device by etching through a top layer of a silicon on insulator (SOI) substrate and filling the resulting openings with doped polysilicon that extends below the bottom surface of the movable element of the MEMS device. The various methods are undesirable for an SOI starting material in that they require too many processing steps for bump formation, therefore increasing manufacturing costs of such MEMS devices.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 shows a partial cross-sectional view of a layered wafer microelectromechanical systems (MEMS) structure having anti-stiction bumps made according to an embodiment of the present disclosure;

FIG. 2 shows a partial cross-sectional view of another layered wafer microelectromechanical systems (MEMS) structure having anti-stiction bumps made according to the embodiment of the present disclosure;

FIG. 3 shows a flowchart of a process for producing either of the layered wafer MEMS structures of FIGS. 1 and 2 according to another embodiment;

FIG. 4 shows a partial cross-sectional view of a substrate at an initial stage of manufacture for incorporation in the layered wafer MEMS structure of FIG. 1;

FIG. 5 shows a partial cross-sectional view of the substrate of FIG. 4 in a subsequent stage of processing;

FIG. 6 shows a partial cross-sectional view of the substrate of FIG. 5 in a subsequent stage of processing;

FIG. 7 shows a partial cross-sectional view of the substrate of FIG. 6 in a subsequent stage of processing;

FIG. 8 shows a partial cross-sectional view of the substrate of FIG. 7 with another substrate coupled thereto in a subsequent stage of processing thus forming a layered wafer structure;

FIG. 9 shows a partial cross-sectional view of the layered wafer structure of FIG. 8 in a subsequent stage of processing;

FIG. 10 shows a partial cross-sectional view of a substrate at an initial stage of manufacture for incorporation in the layered wafer MEMS structure of FIG. 2;

FIG. 11 shows a partial cross-sectional view of the substrate of FIG. 10 in a subsequent stage of processing;

FIG. 12 shows a partial cross-sectional view of the substrate of FIG. 11 in a subsequent stage of processing;

FIG. 13 shows a partial cross-sectional view of the substrate of FIG. 12 in a subsequent stage of processing;

FIG. 14 shows a partial cross-sectional view of the substrate of FIG. 13 with another substrate coupled thereto in a subsequent stage of processing thus forming a layered wafer structure; and

FIG. 15 shows a partial cross-sectional view of the layered wafer structure of FIG. 14 in a subsequent stage of processing.

### DETAILED DESCRIPTION

According to the embodiments of the present disclosure, a method is disclosed for producing a layered wafer structure having anti-stiction bumps. More particularly, the anti-stiction bumps are produced under a microelectromechanical systems (MEMS) structure. In an embodiment, anti-stiction bumps are created between two wafers of a layered wafer structure, such as a silicon on insulator (SOI) layered wafer structure. In particular, anti-stiction bumps are formed in the surface of either the wafers prior to forming the insulator layer. Following coupling of the handle and device substrates, at least a portion of the insulator layer is removed to expose the anti-stiction bumps. Since the bumps are formed in a substrate of the layered wafer structure prior to wafer bonding, no additional process steps are required to create the anti-stiction bumps thus yielding a simplified, low cost solution to forming anti-stiction features.

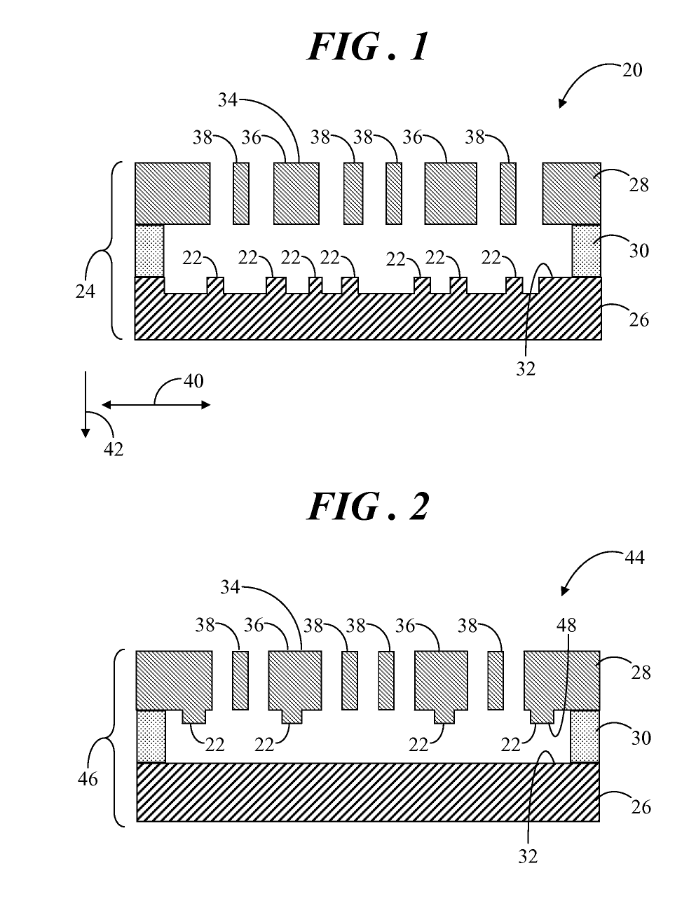

FIG. 1 shows a partial cross-sectional view of a microelectromechanical systems (MEMS) structure 20 having anti-stiction bumps 22 made according to an embodiment of the present disclosure. MEMS structure 20 includes a layered wafer structure 24 formed from a first wafer, referred to herein as a handle substrate 26, and a second wafer, referred to herein as a device substrate 28. Handle substrate 26 and device substrate 28 are coupled together, and an insulator layer 30 is interposed between handle and device substrates 26 and 28, respectively.

Layered wafer structure 24 is based on a wafer structure technology, known as silicon on insulator (SOI) technology. SOI refers to the use of a layered silicon-insulator-silicon substrate, in lieu of the conventional silicon substrates used in semiconductor manufacturing. SOI-based devices differ from conventional silicon-built devices in that the silicon junction, e.g., device substrate 28, is above an electrical insulator, e.g., insulator layer 30. Device substrate 28 may be a single-crystal silicon layer and insulator layer 30 may be an embedded oxide layer, such as silicon dioxide. However, materials used for device substrate 28 and insulator layer 30 may vary in accordance with the particular application. The inclusion of the embedded insulator layer 30 can result in a reduction in leakage current, improved chip performance, and/or reduced power consumption compared to bulk silicon technology. Although a layered wafer structure based on SOI technology is discussed herein, it should be understood that embodiments of the present disclosure may be applied to other layered wafer structures such as a fully or partially processed complementary metal-oxide-semiconductor (CMOS) wafer.

In the illustrated embodiment, anti-stiction bumps 22 are created in handle substrate 26 from a surface 32 of handle substrate 26 and MEMS structure 20 is formed in device substrate 28. In particular, MEMS structure 20 includes a movable element 34, sometimes referred to as a proof mass, formed in device substrate 28. Anti-stiction bumps 22 are created in handle substrate 26 underlying movable element 34. In an exemplary embodiment, movable element 34 may include movable fingers 36 interposed between fixed fingers 38 of MEMS structure 20. In such an embodiment, movable fingers 36 can move laterally relative to fixed fingers 38 in response to a particular stimulus, such as acceleration. This stimulus is represented by a bi-directional arrow 40.

In some instances, a change in capacitance may be detected between movable fingers 36 and fixed fingers 38 in response to stimulus 40. The sensed stimulus 40 can be converted to an electrical signal indicative of the magnitude of the stimulus. Although the intended movement of movable element 34 may be lateral in response to stimulus 40, movable element 34 could be subjected to forces out-of-plane relative to movable element 34, as represented by a vertically arranged arrow 42. These forces could cause moveable element 34 to come into contact with surface 32 of handle substrate 26. Anti-stiction bumps 22 are appropriately positioned to largely limit the occurrence of, or prevent, stiction between movable element 34 and surface 32 of handle substrate 26. Although an exemplary MEMS structure 20 is discussed in connection with the layered wafer structure, it should be understood that embodiments of the present disclosure may be applied to a wide variety of layered wafer device structures having moving parts, e.g., sensors and switches, in which problems with stiction are to be addressed.

FIG. 2 shows a partial cross-sectional view of another MEMS structure 44 having anti-stiction bumps 22 made according to the embodiment of the present disclosure. MEMS structure 44 includes an SOI-based layered wafer structure 46 that includes handle substrate 26, device substrate 28, and insulator layer 30 interposed between handle and devices wafers 26 and 28, respectively. MEMS structure 44 additionally includes movable element 34 having movable fingers 36 interposed between fixed fingers 38 of MEMS structure 20. However, in this exemplary embodiment, anti-stiction bumps 22 are created in device substrate 28 and are located in a bottom surface 48 of movable element 34. Anti-stiction bumps 22 are appropriately located in bottom surface 48 of movable element 34 to largely limit the occurrence of, or prevent stiction between, movable element 34 and surface 32 of handle substrate 26 should movable element 34 be subjected to force 42. Although surface 32 of handle substrate 26 underlying anti-stiction bumps 22 is shown as being substantially planar, this is not a requirement. In alternative embodiments, surface 32 may include cavities, posts, or other non-planar features in accordance with particular configuration requirements of MEMS structure 244.

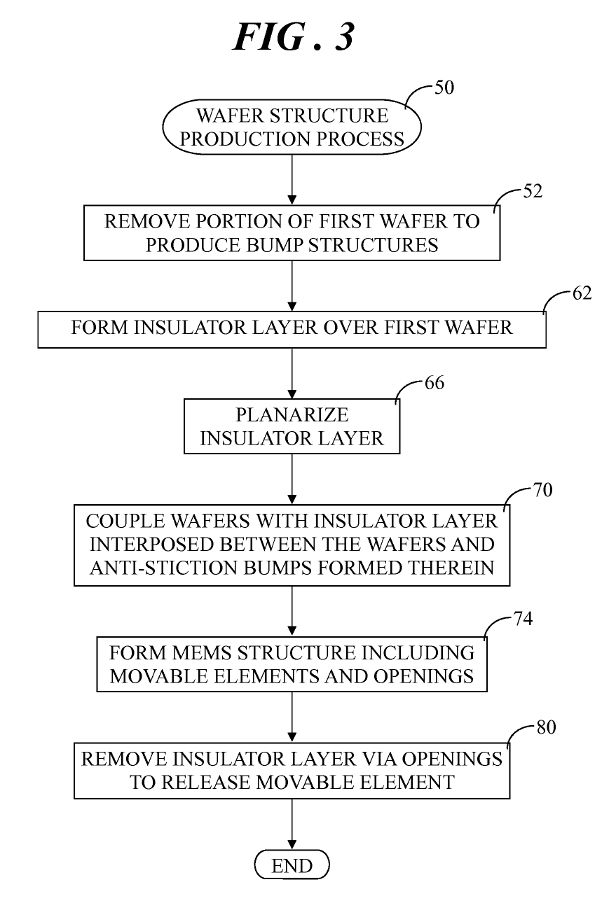

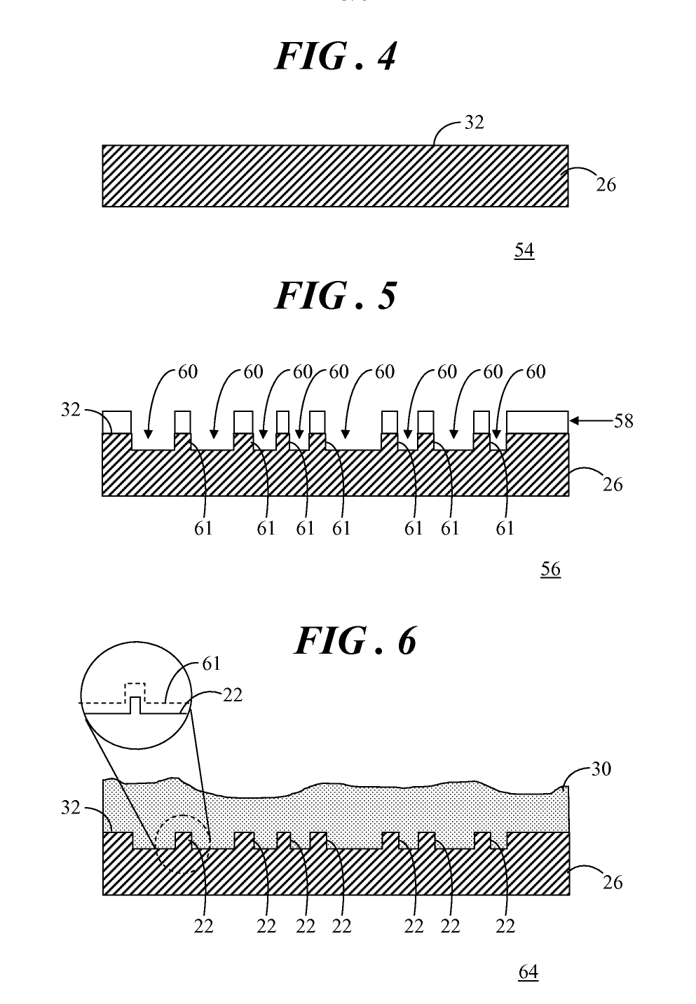

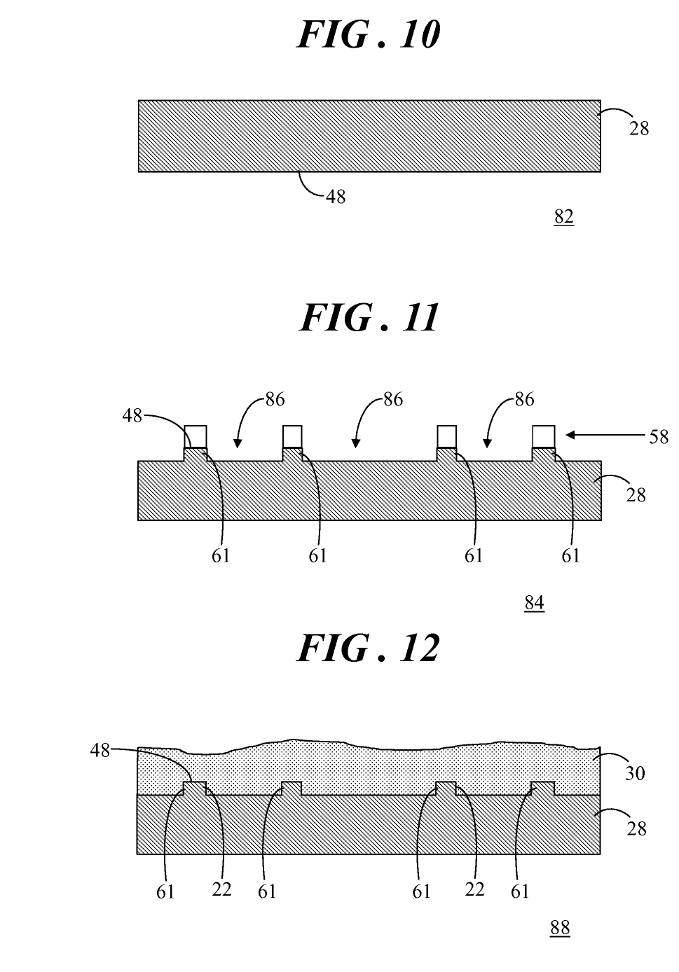

FIG. 3 shows a flowchart of a process 50 for producing either of layered wafer MEMS structures 20 and 44 (FIGS. 1 and 2) according to another embodiment. Process 50 provides the methodology for creating anti-stiction bumps 22 between handle substrate 26 and device substrate 28 in MEMS structures 20 and 44 that use layered wafer structures 24 and 46 for a starting material. Process 50 will first be discussed in connection with the production of layered wafer MEMS structure 20 (FIG. 1), and attention will be directed toward FIGS. 4-9. Following the discussion of process 50 to produce MEMS structure 20, process 50 will be discussed in connection with the production of MEMS structure 44, and attention will be directed toward FIGS. 10-15.

Process 50 implements known and developing layered wafer manufacturing techniques and MEMS micromachining technologies to cost effectively yield either of layered wafer MEMS structures 20 and 44 having anti-stiction bumps 22. Process 50 is described below in connection with the fabrication of a single MEMS structure 20, or alternatively MEMS structure 44. However, it should be understood by those skilled in the art that the following process allows for concurrent wafer-level manufacturing of a plurality of MEMS structures 20, or alternatively, MEMS structures 44. The structures 20 or 44 can then be cut, or diced, in a conventional manner to provide individual MEMS structures 20 or 44 that can be packaged and integrated into an end application.

In general, process 50 begins with a task 52. At task 52, a portion of a first substrate, i.e., a first wafer, is removed to produce bump structures.

Referring to FIGS. 4 and 5 in connection with task 52, FIG. 4 shows a partial cross-sectional view of handle substrate 26 at an initial stage 54 of manufacture for incorporation in layered wafer MEMS structure 20 (FIG. 1), and FIG. 5 shows a partial cross-sectional view of handle substrate 26 in a subsequent stage 56 of processing. Handle substrate 26, as the first wafer, may be a silicon wafer that is suitably patterned with a resist material 58 to form a temporary mask that protects selected areas of handle substrate 26 during subsequent processing steps. Handle substrate 26 is then etched using, for example, a deep reactive ion etch (DRIE) process, to remove a portion 60 of handle substrate 26 that is not masked by resist material 58 to produce bump structures 61. A DRIE process may be implemented to create deep, steep-sided bump structures 61. However, alternative embodiments may use a Potassium Hydroxide (KOH) etch technique, or any other suitable process for creating bump structures 61. As will be discussed in various embodiments below, anti-stiction bumps 22 are formed from bump structures 61. That is, bumps structures 61 constitute the starting material for providing anti-stiction bumps 22.

With reference back to FIG. 3, following the production of one or more bump structures 61 in handle substrate 26 at task 52, process 50 continues with a task 62. At task 62, insulator layer 30 is formed over surface 32 of handle substrate 26. Bump structures 61 may be partially or fully embedded in insulator layer 30. Alternatively, insulator layer 30 may be formed on a portion of surface 32, avoiding those locations where bump structures 61 are formed so that structures 61 are not embedded in insulator layer 30.

Referring to FIG. 6 in connection with task 62, FIG. 6 shows a partial cross-sectional view of handle substrate 26 of FIG. 5 in a subsequent stage 64 of processing. In an embodiment, insulator layer 30 may be an oxide layer grown on surface 32 of handle substrate 26. For example, insulator layer 30 may be formed on surface 32 at an elevated temperature in the presence of an oxidizing agent, in a process known as thermal oxidation. This technique forces the oxidizing agent to diffuse into handle substrate 26 at high temperature and react with it to “grow” the oxide. Thus, thermal oxide is a “grown” oxide layer that has high uniformity and high dielectric strength to serve as insulator layer 30.

As illustrated in an exploded view of FIG. 6, a thermal oxidation process can result in at least a partial consumption of bump structures 61 to form anti-stiction bumps 22. That is, the diffusion and reaction processes of thermal oxidation can result in anti-stiction bumps 22 that are shorter and/or narrower than bump structures 61 from which bumps 22 were formed. This is represented in the exploded view by bump structure 61 being illustrated in a dashed line form and anti-stiction bump 22 being illustrated in a solid line form. In this example, bumps 22 are fully covered by the oxide insulator layer 30 following growth of insulator layer 30 via a thermal oxidation process. In other words, insulator layer 30 is thicker than the height of bumps 22. However, in accordance with known methodologies, thermal oxidation can be performed on selected areas of handle substrate 26 and blocked on others so that bump structures 61 are not fully covered by insulator layer 30. In such an instance, bump structures 61 need not be consumed by the oxidizing agent, and thus bump structures 61 themselves would constitute anti-stiction bumps 22.

With reference back to FIG. 3, following the formation of insulator layer 30 over surface 32 of handle substrate 26 at task 62, process 50 continues with a task 66. At task 66, insulator layer 30 is planarized. In an embodiment, the surface of insulator layer 30 may be planarized without exposing anti-stiction bumps 22.

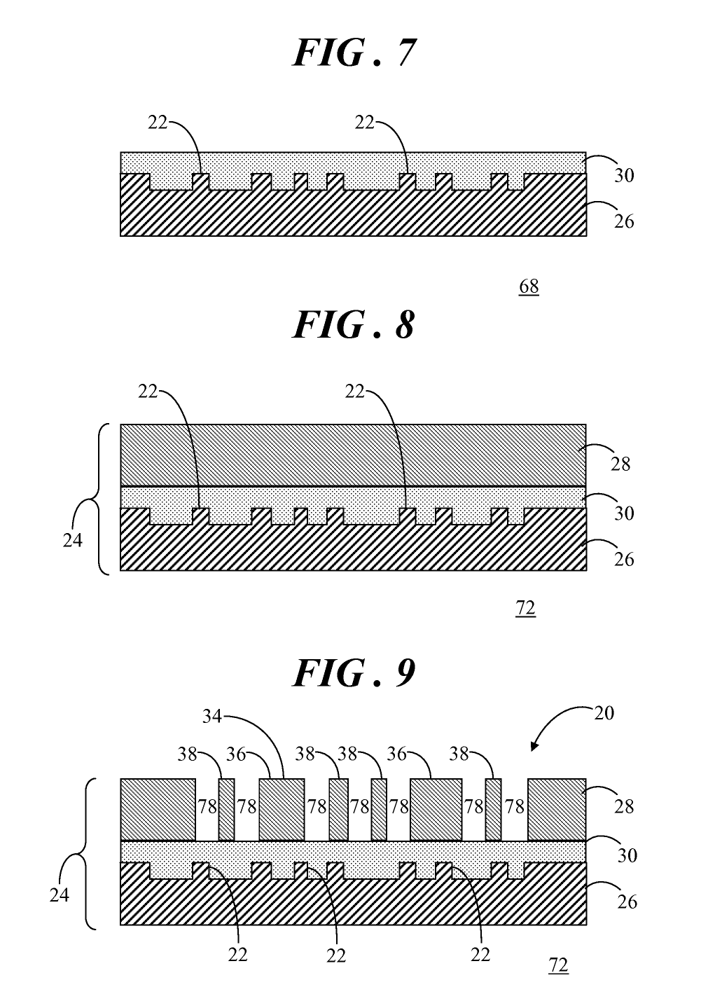

Referring to FIG. 7 in connection with task 66, FIG. 7 shows a partial cross-sectional view of handle substrate 26 in a subsequent stage 68 of processing. In an embodiment, a chemical mechanical planarization (CMP) technique may be implemented to planarize, i.e., smooth, the surface of insulator layer 30 to form a planarized insulator layer 30. CMP typically uses an abrasive and/or corrosive chemical slurry in conjunction with a polishing pad. The pad and wafer are pressed together by a polishing head, and the head is rotated to remove insulator layer 30 in order to even out any irregular topography, thus making insulator layer 30 flat or planar. Although CMP is discussed herein, other known and upcoming processes may be utilized to make insulator layer 30 flat or planar.

With reference back to FIG. 3, following planarization of insulator layer 30 at task 66, process 50 continues with a task 70. At task 70, device substrate 28, as a second wafer, is coupled to the first wafer, i.e., handle substrate 26, with insulator layer 30 interposed between handle and device substrates 26 and 28, respectively.

Referring to FIG. 8 in connection with task 70, FIG. 8 shows a partial cross-sectional view of the substrate of FIG. 7 with another substrate coupled thereto in a subsequent stage 72 of processing thus forming layered wafer structure 24. In particular, handle substrate 28 with anti-stiction bumps 22 is coupled to device substrate 26 with insulator layer 30 substantially filling the gap between substrates 26 and 28. Coupling may be accomplished using any suitable attachment process and material, for example, glass frit bonding, silicon fusion bonding, metal eutectic bonding, anodic bonding, thermal compression bonding, and the like.

With reference back to FIG. 3, following bonding of device substrate 26 with handle substrate 28 at task 70, process 50 continues with a task 74. At task 74, processing steps are performed to form MEMS structure 20 in device substrate 26 of layered wafer structure 24.

Referring now to FIG. 9 in connection with task 74, FIG. 9 shows a partial cross-sectional view of layered wafer structure 24 in a subsequent stage 76 of processing. At task 74, conventional and developing MEMS surface micromachining process steps are performed, such as deposition, patterning, and etching, to produce MEMS structure 20 including openings 78 extending through device wafer 28. Appropriately patterned and etched openings 78 yields movable element 34 having movable fingers 36 that are movable relative to fixed fingers 38.

With reference back to FIG. 3, following processing to produce MEMS structure 20 and openings 78 extending through device substrate 26 at task 74, process 50 continues with a task 80. At task 80, at least a portion of insulator layer 30 underlying MEMS structure 20 is removed to release movable element 34 and to expose anti-stiction bumps 22. By way of example, an appropriate etchant may be introduced via openings 78 (FIG. 9) to remove the underlying sacrificial oxide insulator layer 30 in order to release movable element 34 and to expose anti-stiction bumps 22 as illustrated in FIG. 1.

Although only a single MEMS structure 20 is formed in device substrate 26 for illustrative purposes, it should be understood that alternative embodiments may include more than one MEMS device each having at least one movable element formed in device substrate 26. In still other alternative embodiments, MEMS devices may be formed in both device substrate 26 and handle substrate 28.

Now referring to FIGS. 10-15, FIGS. 10-15 represent an adaption of process 50 in which anti-stiction bumps 22 are created on bottom surface 48 (FIG. 2) of device substrate 28, and consequently, on movable element 34 of MEMS device structure 44 (FIG. 2).

Referring to FIGS. 10 and 11, FIG. 10 shows a partial cross-sectional view of a first wafer, and in particular, device substrate 28, at an initial stage 82 of manufacture for incorporation in the layered wafer MEMS structure 44 and FIG. 11 shows a partial cross-sectional view of the device substrate 28 of FIG. 10 in a subsequent stage 84 of processing. In accordance with task 52 (FIG. 3) of process 50 (FIG. 3), bottom surface 48 of device substrate 28 (shown flipped in FIG. 11) is suitably patterned with resist material 58. Device substrate 28 is then etched to remove a portion 86 of material from bottom surface 48 of device substrate 28 that is not masked by resist material 58 to produce bump structures 61.

FIG. 12 shows a partial cross-sectional view of device substrate 28 of FIG. 11 in a subsequent stage 88 of processing. In accordance with task 62 (FIG. 3) of process 50 (FIG. 3), insulator layer 30 is formed over the first wafer (i.e., device substrate 28) to cover bumps structures 61. In this embodiment insulator layer 30 may be deposited using chemical vapor deposition, or any other suitable deposition process. Such deposition processes need not consume bump structures 61. Accordingly, bump structures 61 themselves constitute anti-stiction bumps 22 in this embodiment. In this example, anti-stiction bumps 22 are fully embedded in insulator layer 30. However, suitable patterning, deposition, and etching processes may be performed to form insulator layer 30 on a portion of surface 32 without fully embedding anti-stiction bumps 22 therein. In alternative embodiments, insulator layer 30 may be an oxide “grown” by thermal oxidation on bottom surface 48 of device substrate 28, as previously discussed.

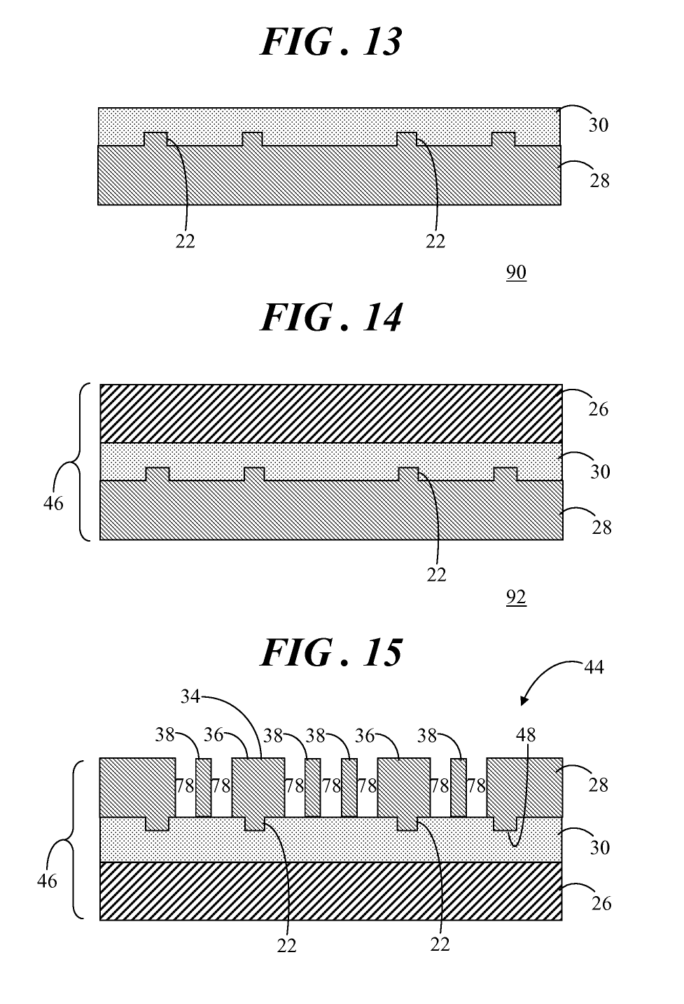

FIG. 13 shows a partial cross-sectional view of device substrate 28 of FIG. 12 in a subsequent stage 90 of processing. In accordance with task 66 (FIG. 3) of process 50 (FIG. 3), insulator layer 30 is planarized using, for example chemical mechanical planarization to smooth insulator layer 30, i.e., to form a planarized insulator layer 30.

FIG. 14 shows a partial cross-sectional view of device substrate 28 of FIG. 13 with another substrate, i.e., handle substrate 26, coupled thereto in a subsequent stage 92 of processing thus forming layered wafer structure 46 with anti-stiction bumps 22 formed therein. Coupling is performed in accordance with task 70 (FIG. 3) of process 50 (FIG. 3) so that handle substrate 26, as a second wafer, is coupled to device substrate 28 with insulator layer 30 interposed between handle and device substrates 26 and 28, respectively. Coupling may be may be accomplished using, for example, glass frit bonding, silicon fusion bonding, metal eutectic bonding, anodic bonding, thermal compression bonding, and the like.

FIG. 15 shows a partial cross-sectional view of layered wafer structure 46 of FIG. 14 in a subsequent stage 94 of processing. In accordance with task 74 (FIG. 3) of process 50 (FIG. 3), layered wafer structure 46 may be flipped and processing steps are performed to form MEMS structure 44 in device substrate 26 of layered wafer structure 46. For example, conventional and developing MEMS surface micromachining process steps are performed, such as deposition, patterning, and etching, to produce MEMS structure 44 including openings 78 extending through device wafer 28. Appropriately patterned and etched openings 78 yields movable element 34 having movable fingers 36 that are movable relative to fixed fingers 38. Furthermore, movable element 34 includes appropriately located anti-stiction bumps 22 on bottom surface 48.

Of course, processing is continued through execution of task 80 (FIG. 3) of production process 50 (FIG. 3) to remove the underlying insulator layer 30 to release movable element 34 and expose anti-stiction bumps 22 of MEMS structure 44, as shown in FIG. 2.

Embodiments described herein comprise a method for producing a layered wafer structure having anti-stiction bumps. The anti-stiction bumps are created between two wafers of the layered wafer structure, such as a silicon on insulator (SOI) layered wafer structure. In particular, anti-stiction bumps are formed in at least one of the internal surfaces of either the wafers prior to forming the insulator layer. The anti-stiction bumps are at least partially embedded in the insulator layer. A MEMS structure having a movable element is formed in one of the two wafers. At least a portion of the insulator layer is removed to release the movable element and to expose the anti-stiction bumps. The anti-stiction bumps are appropriately positioned to largely limit the occurrence of, or prevent, stiction between the movable element and the surface of the underlying substrate surface. Since the anti-stiction bumps are formed in a substrate of the layered wafer structure prior to wafer bonding, no additional process steps and materials costs are required to create the anti-stiction bumps, thus yielding a simplified, low cost solution to forming anti-stiction features. Moreover, the methodology is cost-effective, readily implemented, and adaptable to existing layered wafer structure manufacturing and micromachining tools and techniques.

Although the preferred embodiments of the invention have been illustrated and described in detail, it will be readily apparent to those skilled in the art that various modifications may be made therein without departing from the spirit of the invention or from the scope of the appended claims. For example, the anti-stiction bumps can take on various shapes and sizes then those which are shown, and they can be positioned at any suitable region or regions in either of the substrate wafers.

What is claimed is:

1. A method for producing a layered wafer structure having an anti-stiction bump formed therein comprising:
removing a portion of a first wafer from a surface of said first wafer to produce a bump structure in said first wafer, said anti-stiction bump being formed from said bump structure;
forming an insulator layer on said surface of said first wafer;
coupling a second wafer to said first wafer with said insulator layer interposed between said first and second wafers to produce said layered wafer structure having said anti-stiction bump formed therein;
forming openings extending through one of said first and second wafers of said layered wafer structure; and
removing, via said openings, at least a portion of said insulator layer underlying said one of said first and second wafers.

2. A method as claimed in claim 1 wherein said bump structure is one of a plurality of bump structures, and said removing said portion of said first wafer comprises etching into said surface of said first wafer to form said plurality of bump structures.

3. A method as claimed in claim 2 wherein said etching operation uses a deep reactive ion etch process.

4. A method as claimed in claim 1 wherein said insulator layer is an oxide layer, and said forming said insulator layer comprises growing said oxide layer on said first wafer using a thermal oxidation process.

5. A method as claimed in claim 4 wherein said growing operation comprises growing said oxide layer on said bump structure, said growing operation consuming at least a portion of said bump structure to form said anti-stiction bump in said first wafer.

6. A method as claimed in claim 5 wherein said anti-stiction bump is covered with said oxide layer following said growing operation, and said removing operation includes exposing said anti-stiction bump from said oxide layer.

7. A method as claimed in claim 1 wherein said forming said insulator layer comprises depositing said insulator layer on said first wafer using a deposition process without consumption of said bump structure such that said bump structure constitutes said anti-stiction bump.

8. A method as claimed in claim 7 wherein said anti-stiction bump is covered with said insulator layer following said depositing operation, and said removing operation includes exposing said anti-stiction bump from said insulator layer.

9. A method as claimed in claim 1 further comprising planarizing said insulator layer prior to said coupling operation to produce a planarized insulator layer.

10. A method as claimed in claim 1 wherein said one of said first and second wafers is a single-crystal silicon layer.

11. A method as claimed in claim 1 wherein:
said forming said openings includes forming a microelectromechanical systems (MEMS) structure in said one of said first and second wafers of said layered wafer structure, said openings producing a movable element of said MEMS structure; and
said removing said at least a portion of said insulator layer includes removing said insulator layer underlying said movable element to release said movable element of said MEMS structure.

12. A method as claimed in claim 10 wherein said first wafer is a support substrate, said movable element is formed in said second wafer, and said anti-stiction bump is formed in said support substrate underlying said movable element.

13. A method as claimed in claim 10 wherein said first wafer is a device substrate, said movable element is formed in said device substrate, and said anti-stiction bump is located in a bottom surface of said movable element of said MEMS structure.

14. A method for producing a layered wafer structure having a plurality of anti-stiction bumps formed therein comprising:
removing a portion of a first wafer from a surface of said first wafer to produce a plurality of bump structures in said first wafer, said plurality of anti-stiction bumps being formed from said bump structures;
forming an insulator layer on said surface of said first wafer;
planarizing said insulator layer to produce a planarized insulator layer;
coupling a second wafer to said first wafer with said planarized insulator layer interposed between said first and second wafers to produce said layered wafer structure having said anti-stiction bumps formed therein;
forming a microelectromechanical systems (MEMS) structure in one of said first and second wafers of said layered wafer structure, said forming operation including forming openings extending through said one of said first and second wafers to produce a movable element of said MEMS structure; and
removing, via said openings, at least a portion of said insulator layer underlying said one of said first and second wafers to release said movable element from said planarized insulator layer.

15. A method as claimed in claim 14 wherein said first wafer is a support substrate, said movable element is formed in said second wafer of said layered wafer structure, and said anti-stiction bumps are formed in said support substrate underlying said movable element.

16. A method as claimed in claim 14 wherein said first wafer is a device substrate, said movable element is formed in said device substrate, and said anti-stiction bumps are located in a bottom surface of said movable element of said MEMS structure.

17. A method for producing a layered wafer structure having an anti-stiction bump formed therein comprising:
removing a portion of a first wafer from a surface of said first wafer to produce a bump structure in said first wafer, said anti-stiction bump being formed from said bump structure;
forming an insulator layer on said surface of said first wafer, said insulator layer covering said anti-stiction bump;
planarizing said insulator layer without exposing said anti-stiction bump;
following said planarizing operation, coupling a second wafer to said first wafer with said planarized insulator layer interposed between said first and second wafers to produce said layered wafer structure having said anti-stiction bump formed therein;
forming openings extending through said one of said first and second wafers; and
removing, via said openings, at least a portion of said insulator layer underlying said one of said first and second wafers to expose said anti-stiction bump from said insulator layer.

18. A method as claimed in claim 17 wherein said insulator layer is an oxide layer, and said forming said insulator layer comprises growing said oxide layer on said bump structure using a thermal oxidation process, said growing operation consuming at least a portion of said bump structure to form said anti-stiction bump in said first wafer.

19. A method as claimed in claim 17 wherein said forming said insulator layer comprises depositing said insulator layer on said first wafer using a deposition process without consumption of said bump structure such that said bump structure constitutes said anti-stiction bump.

20. A method as claimed in claim 17 wherein:
said forming said openings includes forming a microelectromechanical systems (MEMS) structure in said one of said first wafer and said second wafer of said layered wafer structure, said openings producing a movable element of said MEMS structure; and
said removing said at least a portion of said insulator layer includes removing said insulator layer underlying said movable element to release said movable element of said MEMS structure.
